(19) United States
(12) Patent Application Publication
(10) Pub. No.: US 2014/0043905 A1
(43) Pub. Date: Feb. 13, 2014

(54) SEMICONDUCTOR MEMORY DEVICE AND METHOD OF MANUFACTURING THE SAME

(71) Applicant: Myung Shik LEE, Seoul (KR)

(72) Inventor: Myung Shik LEE, Seoul (KR)

(21) Appl. No.: 13/605,243

(22) Filed: Sep. 6, 2012

(30) Foreign Application Priority Data
Aug. 8, 2012 (KR) 10-2012-0086881

(51) Int. Cl. H01L 21/28; G11C 16/04

(52) U.S. Cl. 365/185.11; 438/591; 257/E21.209

(57) ABSTRACT

A semiconductor memory device includes a memory cell block formed over a first memory cell region and a second memory cell region defined on a semiconductor substrate, and a voltage supply circuit configured to apply an operating voltage to gate lines of a plurality of memory cells included in the memory cell block, wherein a first air gap disposed between the gate lines in the first memory cell region has a smaller size than a second air gap disposed between the gate lines in the second memory cell region.

### CROSS-REFERENCE TO RELATED APPLICATION

The present application claims priority to Korean patent application number 10-2012-0086881 filed on Aug. 8, 2012, in the Korean Intellectual Property Office, the entire disclosure of which is incorporated by reference herein.

### BACKGROUND

1. Technical Field

Exemplary embodiments relate to a semiconductor memory device and a method of manufacturing the same and, more particularly, to a semiconductor memory device including an air gap and a method of manufacturing the same.

2. Related Art

A semiconductor memory device may include a plurality of memory cells configured to store data and devices configured to perform various operations. High-density integration techniques have become increasingly important for this semiconductor memory device to achieve a large data capacity and light weight. In particular, since memory cells occupy large space in a semiconductor chip, a reduction in size of the memory cells and a reduction in space between adjacent memory cells have become issues.

Among semiconductor memory devices, a NAND flash memory device includes memory cells in units of strings. Isolation layers, formed of insulating materials, are filled between the strings, that is, at isolation regions. The isolation layers serve to block electrical influence between adjacent strings, e.g., interference therebetween.

However, with increasing integration degree of the semiconductor memory device, the isolation layers formed of the insulating materials may have limitations in blocking interference between the strings, which may deteriorate reliability of the semiconductor memory device.

### BRIEF SUMMARY

An embodiment of the present invention relates to a semiconductor memory device which is capable of preventing interference between cells by forming an air gap between word lines of a semiconductor memory device and reducing the difference in threshold voltage between the cells caused by RC delay of voltage applied to the word lines according to positions of the cells, and a method of manufacturing the same.

A semiconductor memory device according to an embodiment of the present invention includes a memory cell block formed over a first memory cell region and a second memory cell region defined on a semiconductor substrate, and a voltage supply circuit configured to apply an operating voltage to gate lines of a plurality of memory cells included in the memory cell block, wherein a first air gap disposed between the gate lines in the first memory cell region has a larger size than a second air gap disposed between the gate lines in the second memory cell region.

A method of manufacturing a semiconductor memory device according to an embodiment of the present invention includes forming first gate line patterns and second gate line patterns in a first memory cell region and a second memory cell region defined on a semiconductor substrate, forming a first insulating layer to have a first air gap formed between the first gate line patterns in the first memory cell region and a second air gap formed between the second gate line patterns in the second memory cell region, and selectively etching the first insulating layer in the second memory cell region to increase dimensions of the second air gap so that the dimensions of the second air gap are greater than dimensions of the first air gap.

A method of manufacturing a semiconductor memory device according to another embodiment of the present invention includes forming first gate line patterns and second gate line patterns in a first memory cell region and a second memory cell region defined on a semiconductor substrate, forming a first insulating layer to have a first air gap formed between the first gate line patterns in the first memory cell region and a second air gap formed between the second gate line patterns in the second memory cell region, and forming an auxiliary layer along an inner wall of the first air gap in the first memory cell region to decrease dimensions of the first air gap so that the dimensions of the first air gap are smaller than dimensions of the second air gap.

### BRIEF DESCRIPTION OF THE DRAWINGS

FIG. 1 is a circuit diagram of a semiconductor memory device according to an embodiment of the present invention;

FIG. 2 is a graph illustrating RC delay of voltage applied to memory cells according to positions of the memory cells in a memory cell array;

FIGS. 3 to 8 are cross-sectional views illustrating a method of manufacturing a semiconductor memory device according to an embodiment of the present invention;

FIGS. 9 to 14 are cross-sectional views illustrating a method of manufacturing a semiconductor memory device according to another embodiment of the present invention;

FIG. 15 is a block diagram illustrating a memory system according to an embodiment of the present invention; and

FIG. 16 is a block diagram of a computing system according to an embodiment of the present invention.

### DETAILED DESCRIPTION

Hereinafter, various embodiments of the present disclosure will be described in detail with reference to the accompanying drawings. The figures are provided to allow those having ordinary skill in the art to understand the scope of the embodiments of the disclosure. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

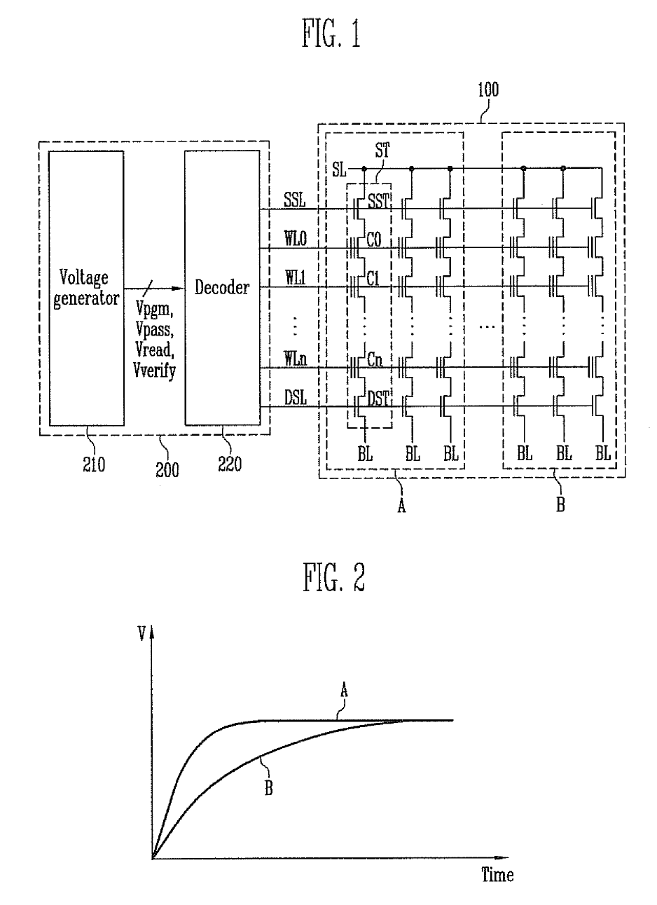

FIG. 1 is a circuit diagram of a semiconductor memory device according to an embodiment of the present invention.

Referring to FIG. 1, a semiconductor memory device may include a memory cell block 100 and a voltage supply circuit 200.

The memory cell block 100 may include a plurality of memory string ST that are coupled between a plurality of bit lines BL and a source line SL.

Each of the memory strings ST may include a drain selection transistor DST, cell strings C0 to Cn and a source selection transistor SST that are coupled in series between each of the bit lines BL and the source line SL. The cell strings may include memory cells C0 to Cn that are coupled in series between the drain selection transistor DST and the source selection transistor SST.

More specifically, the drain selection transistor DST may be coupled between the bit line BL and the cell strings C0 to Cn. The drain selection transistor DST may couple the cell strings C0 to Cn to the bit line BL in response to a voltage applied to a drain selection line DSL. The memory cells C0 to Cn may be operated in response to voltages applied to the word lines WL0 to WLn, respectively. The source selection transistor SST may be coupled between the cell strings C0 to Cn and the source line SL. The source selection transistor SST may couple the cell strings C0 to Cn to the source line SL in response to a voltage applied to a source selection line SSL.

The voltage supply circuit 200 may include a voltage generator 210 and a decoder 220.

The voltage generator 210 may be configured to generate operating voltages, for example, a program voltage Vpgm, a read voltage Vread, a verify voltage Vverify and a pass voltage Vpass, which are applied to the word lines WL0 to WLn coupled to the memory cells C0 to Cn, respectively, during a program operation, a read operation and a verify operation.

The decoder 220 may be configured to selectively apply the operating voltages, generated by the voltage generator 210, to the word lines WL0 to WLn of the memory cell block 100.

The memory cells of the semiconductor memory device may be divided into a first memory cell region A and a second memory cell region B according to positions where the memory cells are located in the memory cell block 100. The first memory cell region A may be located within the memory cell block 100 such that the first memory cell region A may be located adjacent to the voltage supply circuit 200. The second memory cell region B may be located within the memory cell block 100, except for the first memory cell region A. The second memory cell region B may be more distant from the voltage supply circuit 200 than the first memory cell region A. In other words, the first memory cell region A may be located between the second memory cell region B and the semiconductor substrate in which the voltage supply circuit 200 is arranged.

FIG. 2 is a graph illustrating RC delay of voltage applied to memory cells according to positions of the memory cells in a memory cell array.

Referring to FIG. 2, when an operating voltage is applied to the memory cells arranged in the first memory cell region A and the memory cells arranged in the second memory cell region B as illustrated in FIG. 1, RC delay may lead to different rates in voltage increase. This RC delay may be caused by different lengths of the word lines that vary depending on distances between the memory cells and the voltage supply circuit. As the distant between the memory cells and the voltage supply circuit is increased, the RC delay may be increased. The RC delay may cause threshold voltages of the memory cells in the first memory cell region A to be programmed higher than those of the memory cells in the second memory cell region B during a program operation.

In an embodiment of the present invention, in order to reduce the difference in threshold voltage between the memory cells in the first and second memory cell regions A and B, critical dimensions of an air gap formed between gate lines in the second memory cell region B may be increased to be greater than those of an air gap formed between gate lines in the first memory cell region A to decrease permittivity in the second memory cell region B, thus reducing RC delay.

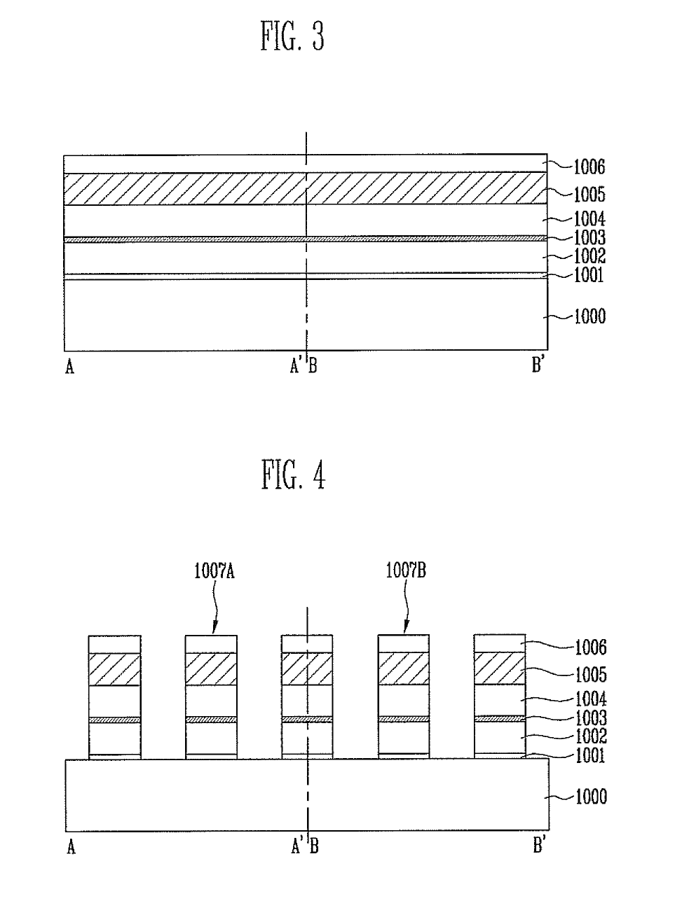

FIGS. 3 to 8 are cross-sectional views illustrating a method of manufacturing a semiconductor memory device according to an embodiment of the present invention.

Referring to FIG. 3, a tunnel insulating layer 1001 and a first conductive layer 1002, which is configured to be used as a floating gate, may be sequentially formed over a semiconductor substrate 1000. A first memory cell region A-A′ and a second memory cell region B-B′, as illustrated in FIG. 1, may be defined on the semiconductor substrate 1000. The tunnel insulating layer 1001 may include an oxide layer, and the first conductive layer 1002 may include a polysilicon layer. For example, the first conductive layer 1002 may contain a doped polysilicon layer injected with impurities or an undoped polysilicon layer not injected with impurities. Subsequently, though not illustrated in FIG. 3, a general isolation process may be performed in order to form isolation layers.

Subsequently, a dielectric layer 1003, a second conductive layer 1004, which is configured to be used as a control gate, a metal gate layer 1005 and a hard mask layer 1006 may be sequentially formed over the first conductive layer 1002. The dielectric layer 1003 may have an ONO structure in which an oxide layer, a nitride layer and an oxide layer are sequentially stacked. Alternatively, the dielectric layer 1003 may be formed by alternately stacking nitride layers and oxide layers. Alternatively, the dielectric layer 1003 may be formed as a single layer formed of high-k dielectrics. The second conductive layer 1004 may include a polysilicon layer, for example, a doped polysilicon layer. The metal gate layer 1005 may include a tungsten layer, a titanium layer, a cobalt layer or a metal silicide layer. The hard mask layer 1006 may include an oxide layer, a nitride layer, or a double-layer structure including an oxide layer and a nitride layer.

Referring to FIG. 4, a patterning process may be performed to form first gate line patterns 1007A in the first memory cell region A-A′ and second gate line patterns 1007B in the second memory cell region B-B′. The first gate line patterns 1007A and the second gate line patterns 1007B may be arranged in a direction crossing isolation regions.

Each of the first and second gate line patterns 1007A and 10076 may be formed of the tunnel insulating layer 1001, the first conductive layer 1002, the dielectric layer 1003, the second conductive layer 1004, the metal gate layer 1005 and the hard mask layer 1006 that are stacked over the semiconductor substrate 1000.

Subsequently, though not illustrated in FIG. 4, top portions of the isolation layers of the exposed isolation regions may be etched so that the top portions of the isolation layers may be placed at lower positions than the tunnel insulating layers 1001. In this manner, in subsequent processes of forming an air gap, the air gap may extend to the lower positions than the tunnel insulating layer 1001.

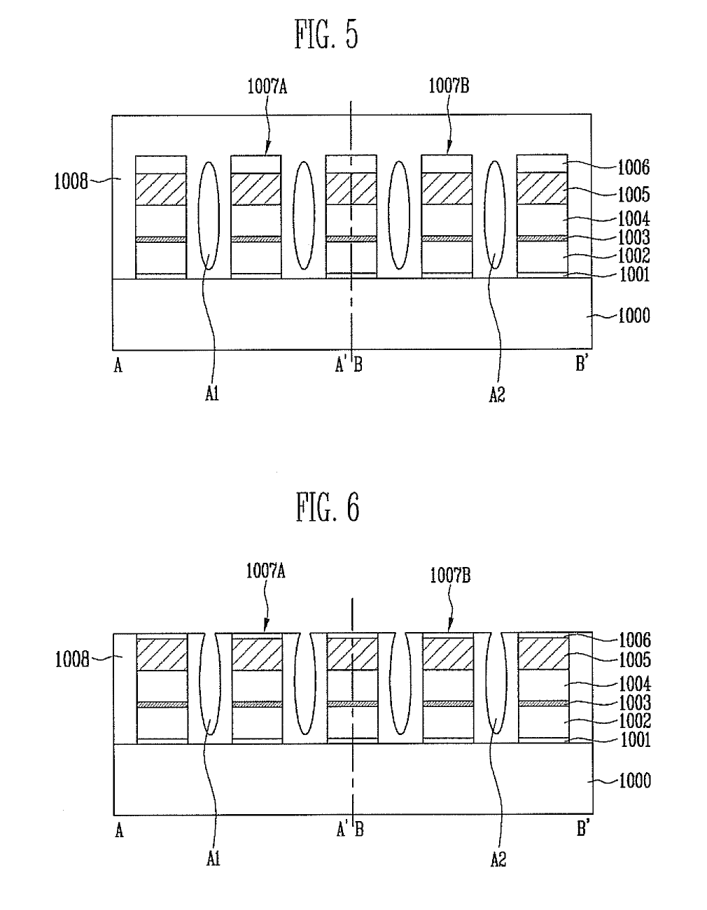

Referring to FIG. 5, a first insulating layer 1008 may be formed over an entire structure including the first and second gate line patterns 1007A and 1007B. The first insulating layer 1008 may be provided to form spacers on sidewalk of a gate line pattern configured as a selection transistor that is located at an outermost edge, among the first and second gate line patterns 1007A and 1007B. When the first insulating layer 1008 is formed, spaces between the gate line patterns may not be completely filled with the first insulating layer 1008 since the spaces between the gate line patterns are small. As a result, a first air gap A1 may be formed between the first gate line patterns 1007A, and a second air gap A2 may be formed between the second gate line patterns 1007B.

Referring to FIG. 6, an etch-back process may be performed to expose the first air gap A1 formed between the first gate line patterns 1007A and the second air gap A2 formed between the second gate line patterns 1007B. As a result, each of the first and second air gaps A1 and A2 may have a top opening. The first insulating layer 1008 may be etched by using the aforementioned etch-back process so that the first insulating layer 1008 may remain on the sidewalls of the gate line pattern for the selection transistor.

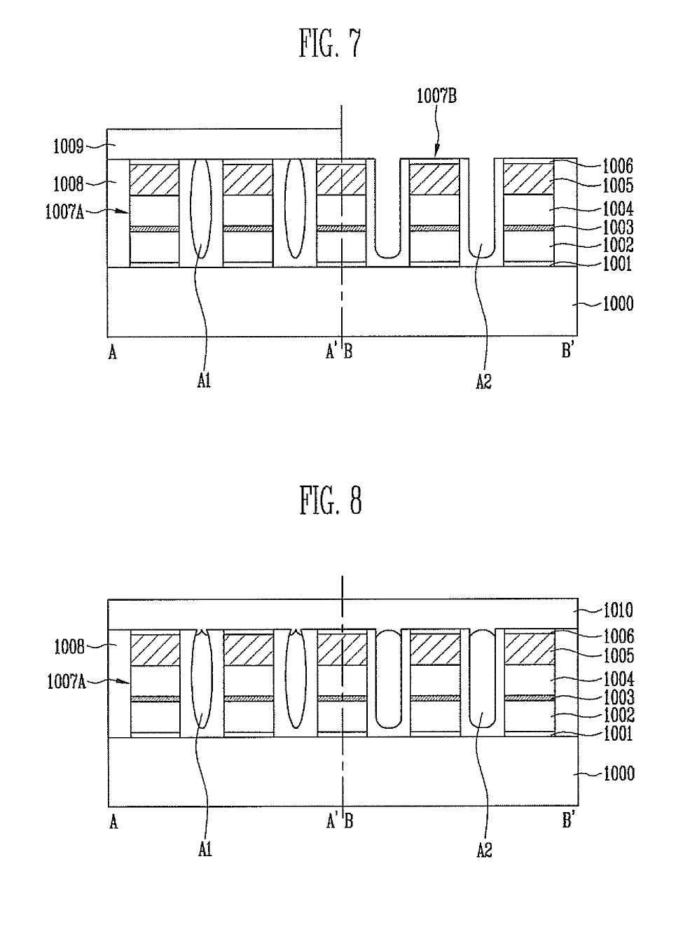

Referring to FIG. 7, a mask pattern 1009 may be formed. The mask pattern 1009 may cover top portions of the first gate line patterns 1007A. The mask pattern 1009 may include a photoresist pattern.

Subsequently, an etch process may be performed to increase a size of the second air gap A2 having the top opening between the second gate line patterns 1007B opened by the mask pattern 1009. As a result, the critical dimensions of the second air gap A2 may be greater than the critical dimensions the first air gap A1.

Referring to FIG. 8, after the mask pattern is removed, a second insulating layer 1010 may be formed over an entire structure including the first and second air gaps A1 and A2 exposed by the etch-back process. Here, the second insulating layer 1010 may include an interlayer insulating layer. The second insulating layer 1010 may include an oxide layer.

When the second insulating layer 1010 is formed, the top openings formed by exposing the top portions of first and second air gaps A1 and A2 may be closed by the second insulating layer 1010.

As set forth above, according to an embodiment of the present invention, air gaps may be formed between gate lines to prevent interference between cells. In addition, critical dimensions of the air gap formed between the gate line patterns in the second memory cell region B relatively distant from a voltage supply circuit may be greater than those of the air gap formed between the gate line patterns in the first memory cell region A relatively close to the voltage supply circuit. Therefore, capacitance between the gate line patterns arranged in the second memory cell region B may be decreased to reduce RC delay, and a change in threshold voltage distribution depending on the distance from the voltage supply circuit may be inhibited.

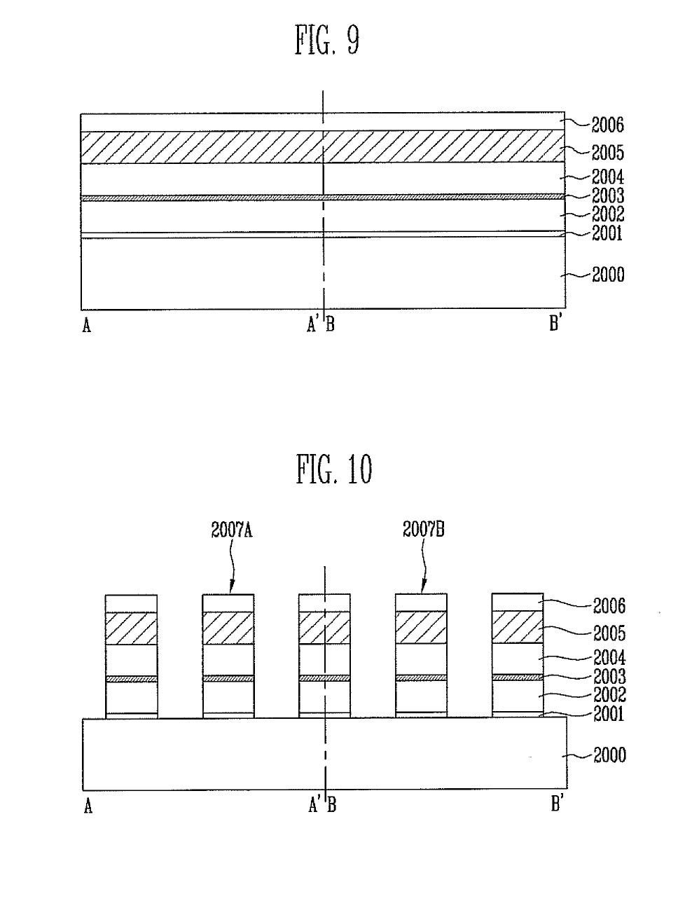

FIGS. 9 to 14 are cross-sectional views illustrating a method of manufacturing a semiconductor memory device according to another embodiment of the present invention.

Referring to FIG. 9, a tunnel insulating layer 2001 and a first conductive layer 2002, which is configured to be used as a floating gate, may be sequentially formed over a semiconductor substrate 2000. The first memory cell region A-A′ and the second memory cell region B-B′, as illustrated in FIG. 1, may be defined on the semiconductor substrate 2000. The tunnel insulating layer 2001 may include an oxide layer. The first conductive layer 2002 may include a polysilicon layer. For example, the first conductive layer 2002 may include a doped polysilicon layer injected with impurities or an undoped polysilicon layer not injected with impurities. Subsequently, although not illustrated in FIG. 9, a general isolation process may be performed to form isolation layers.

Subsequently, a dielectric layer 2003, a second conductive layer 2004, which is configured to be used as a control gate, a metal gate layer 2005 and a hard mask layer 2006 may be sequentially formed over the first conductive layer 2002. The dielectric layer 2003 may have an ONO structure in which an oxide layer, a nitride layer and an oxide layer are sequentially stacked. Alternatively, the dielectric layer 2003 may include a nitride layer and an oxide layer that are sequentially stacked. Alternatively, the dielectric layer 2003 may be formed as a single layer formed of high-k dielectrics. The second conductive layer 2004 may comprise a polysilicon layer, for example, a doped polysilicon layer. The metal gate layer 2005 may include a tungsten layer, a titanium layer, a cobalt layer or a metal silicide layer. The hard mask layer 2006 may include an oxide layer, a nitride layer or a double-layer structure including an oxide layer and a nitride layer.

Referring to FIG. 10, a patterning process may be performed to form first gate line patterns 2007A in the first memory cell region A-A′ and second gate line patterns 2007B in the second memory cell region B-B′. The first gate line patterns 2007A and the second gate line patterns 2007B may be arranged in a direction crossing isolation regions.

Each of the first and second gate line patterns 2007A and 2007B may be formed of the tunnel insulating layer 2001, the first conductive layer 2002, the dielectric layer 2003, the second conductive layer 2004, the metal gate layer 2005 and the hard mask layer 2006 that are stacked over the semiconductor substrate 2000.

Subsequently, although not illustrated in FIG. 10, top portions of the isolation layers of the exposed isolation regions may be etched so that the top portions of the isolation layers may be placed at lower positions than the tunnel insulating layers 2001. In this manner, in subsequent processes of forming an air gap, the air gap may extend to the lower positions than the tunnel insulating layer 2001.

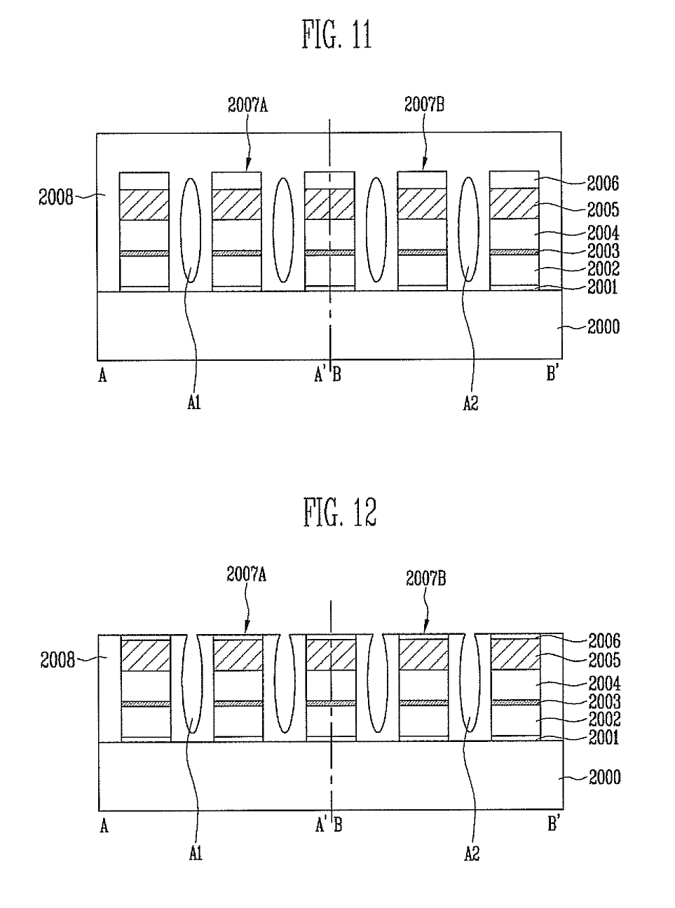

Referring to FIG. 11, a first insulating layer 2008 may be formed over an entire structure including the first and second gate line patterns 2007A and 2007B. The first insulating layer 2008 may be provided to form spacers on both sidewalls of a gate line pattern configured as a selection transistor that is located at an outermost edge, among the first and second gate line patterns 2007A and 2007B. When the first insulating layer 2008 is formed, spaces between the gate line patterns may not be completely filled with the first insulating layer 2008 since the spaces between the gate line patterns are small. As a result, a first air gap A1 may be formed between the first gate line patterns 2007A, and a second air gap A2 may be formed between the second gate line patterns 2007B.

Referring to FIG. 12, an etch-back process may be performed to expose the first air gap formed between the first gate line patterns 2007A and the second air gap A2 formed between the second gate line patterns 2007B. As a result, the first and second air gaps A1 and A2 may have top openings. The first insulating layer 2008 may be etched by using the aforementioned etch-back process so that the first insulating layer 2008 may remain on the sidewalls of the gate line pattern for the selection transistor.

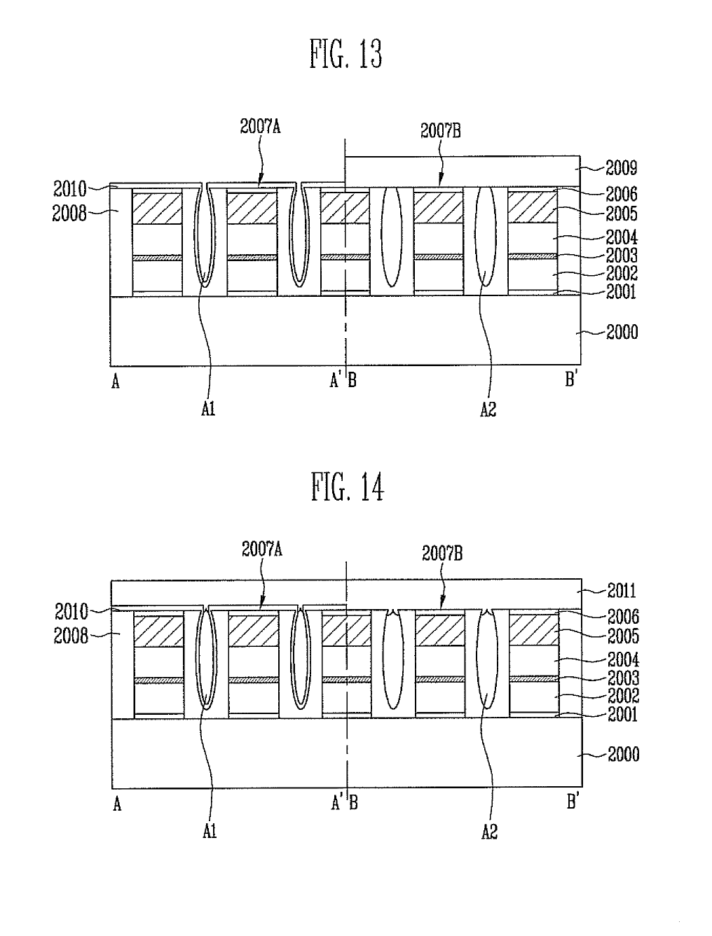

Referring to FIG. 13, a mask pattern 2009 may be formed. The mask pattern 2009 may cover top portions of the second gate line patterns 2007B. The mask pattern 2009 may be a photoresist pattern.

Subsequently, an auxiliary layer 2010 may be formed along an entire structure of the first memory cell region A-A′ opened by the mask pattern 2009. More specifically, the auxiliary layer 2010 may be formed along a surface of the first air gap A1, so that critical dimensions of the first air gap A1 may be smaller than critical dimensions of the second air gap A2.

Referring to FIG. 14, after the mask pattern 2009 is removed, a second insulating layer 2011 may be formed over an entire structure including the first and second air gaps A1 and A2 exposed by the etch-back process. At this time, the second insulating layer 2011 may comprise an interlayer insulating layer. The second insulating layer 2011 may comprise an oxide layer.

When the second insulating layer 2011 is formed, the top openings formed by exposing the top portions of the first and second air gaps A1 and A2 may be closed by the second insulating layer 2011.

As set forth above, according to an embodiment of the present invention, air gaps may be formed between gate lines s to prevent interference between cells. In addition, critical dimensions of the air gap formed between the gate line patterns in the second memory cell region B relatively distant from a voltage supply circuit may be greater than those of the air gap formed between the gate line patterns in the first memory cell region A relatively close to the voltage supply circuit. Therefore, capacitance between the gate line patterns arranged in the second memory cell region B may be decreased to reduce RC delay, and a change in threshold voltage distribution according to the distance from the voltage supply circuit may be inhibited.

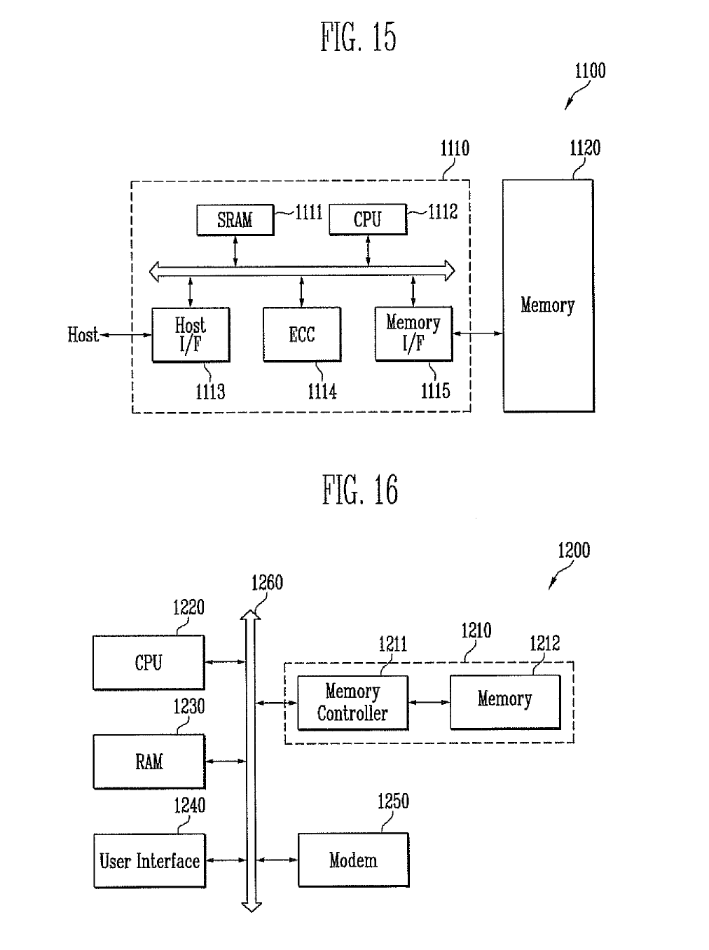

FIG. 15 is a block diagram illustrating a memory system according to an embodiment of the present invention.

As illustrated in FIG. 15, a memory system 1100 according to an embodiment of the present invention may include a non-volatile memory device 1120 and a memory controller 1110.

The non-volatile memory device 1120 may have the semiconductor memory device described with reference to the embodiments described above in connection with FIG. 1 and FIGS. 3 to 14. In addition, the non-volatile memory device 1120 may be a multi-chip package composed of a plurality of flash memory chips.

The memory controller 1110 may be configured to control the non-volatile memory device 1120. The memory controller 1110 may include SRAM 1111, a CPU 1112, a host interface 1113, an ECC 1114 and a memory interface 1115. The SRAM 1111 may function as an operation memory of the CPU 1112. The CPU 1112 may perform the general control operation for data exchange of the memory controller 1110. The host interface 1113 may include a data exchange protocol of a host being coupled to the memory system 1100. In addition, the ECC 1114 may detect and correct errors included in data read from the non-volatile memory device 1120. The memory interface 1115 may perform to interface with the non-volatile memory device 1120. The memory controller 1110 may further include RCM that stores code data to interface with the host.

The memory system 1100 having the above-described configuration may be a solid state disk (SSD) or a memory card in which the memory device 1120 and the memory controller 1110 are combined. For example, when the memory system 1100 is an SSD, the memory controller 1110 may communicate with the outside (e.g., a host) through one of the interface protocols including USB, MMC, PCI-E, SATA, PATA, SCSI, ESDI and IDE.

FIG. 16 is a block diagram illustrating a computing system according to an embodiment of the present invention.

As illustrated in FIG. 16, a computing system 1200 according to an embodiment of the present invention may include a CPU 1220, RAM 1230, a user interface 1240, a modem 1250 and a memory system 1210 that are electrically coupled to a system bus 1260. In addition, when the computing system 1200 is a mobile device, a battery may be further included to apply operating voltage to the computing system 1200. The computing system 1200 may further include application chipsets, a Camera Image Processor (CIS) and mobile DRAM.

As described above in connection with FIG. 15, the memory system 1210 may include a non-volatile memory 1212 and a memory controller 1211.

According to an embodiment of the present invention, an air gap may be formed between word lines of a semiconductor memory device to prevent interference between cells, and a difference in threshold voltage between the cells caused by RC delay of voltage applied to the word lines may be reduced.

What is claimed is:

1. A semiconductor memory device, comprising:
a memory cell block formed over a first memory cell region and a second memory cell region defined on a semiconductor substrate; and
a voltage supply circuit configured to apply an operating voltage to gate lines of a plurality of memory cells included in the memory cell block,
wherein a first air gap disposed between the gate lines in the first memory cell region has a smaller size than a second air gap disposed between the gate lines in the second memory cell region.

2. The semiconductor memory device of claim 1, wherein the first memory cell region is located within the memory cell block, the first memory cell region adjacent to the voltage supply circuit; and the second memory cell region is located within the memory cell block, except for the first memory cell region.

3. The semiconductor memory device of claim 1, wherein the first memory cell region is located between the voltage supply circuit and the second memory cell region.

4. The semiconductor memory device of claim 1, wherein the voltage supply circuit comprises:
a voltage generator configured to generate the operating voltage; and
a decoder configured to selectively apply the operating voltage to the gate lines of the plurality of memory cells.

5. The semiconductor memory device of claim 1, wherein RC delay of the gate lines of each of the first and second memory cell regions changes according to a size of each of the first and second air gaps.

6. A method of manufacturing a semiconductor memory device, the method comprising:
forming first gate line patterns and second gate line patterns in a first memory cell region and a second memory cell region defined on a semiconductor substrate;
forming a first insulating layer so that a first air gap is formed between the first gate line patterns in the first memory cell region and a second air gap is formed between the second gate line patterns in the second memory cell region; and
selectively etching the first insulating layer in the second memory cell region to increase a dimension of the second air gap so that the dimension of the second air gap is substantially greater than a dimension of the first air gap.

7. The method of claim 6, wherein the first memory cell region is located within a region in which a memory cell block is formed, the first memory cell region adjacent to a voltage supply circuit configured to apply an operating voltage to memory cells; and the second memory cell region is located within the region in which the memory cell block is formed, except for the first memory cell region.

8. The method of claim 6, wherein the first memory cell region is located between the second memory cell region and a voltage supply circuit configured to apply an operating voltage to memory cells.

9. The method of claim 6, wherein the forming of the first gate line patterns and the second gate line patterns comprises:
forming a tunnel insulating layer, a conductive layer and a hard mask layer over the semiconductor substrate; and
forming a plurality of gate line patterns in parallel with each other by patterning the hard mask layer, the conductive layer and the tunnel insulating layer.

10. The method of claim 6, wherein the selective etching of the first insulating layer comprises:
etching the first insulating layer to expose top portions of the first and second air gaps;
forming a mask pattern covering the first insulating layer in the first memory cell region and opening the first insulating layer in the second memory cell region; and
etching the first insulating layer to increase the dimension of the second air gap having the top portion exposed in the second memory cell region.

11. The method of claim 10, further comprising, after the etching of the first insulating layer to increase the dimension of the second air gap:
removing the mask pattern; and
forming a second insulating layer over the first insulating layer to cover openings of the first and second air gaps.

12. A method of manufacturing a semiconductor memory device, the method comprising:
forming first gate line patterns and second gate line patterns in a first memory cell region and a second memory cell region defined on a semiconductor substrate;
forming a first insulating layer so that a first air gap is formed between the first gate line patterns in the first memory cell region and a second air gap is formed between the second gate line patterns in the second memory cell region; and
forming an auxiliary layer along an inner wall of the first air gap in the first memory cell region to decrease a dimension of the first air gap so that the dimension of the first air gap is substantially smaller than a dimension of the second air gap.

13. The method of claim 12, wherein the first memory cell region is located within a region in which a memory cell block is formed, the first memory cell region adjacent to a voltage supply circuit configured to apply an operating voltage to memory cells; and the second memory cell region is within the region in which the memory cell block is formed, except for the first memory cell region.

14. The method of claim 12, wherein the first memory cell region is located between the second memory cell region and a voltage supply circuit configured to apply an operating voltage to memory cells.

15. The method of claim 12, wherein the forming of the first gate line patterns and the second gate line patterns comprises:
forming a tunnel insulating layer, a conductive layer and a hard mask layer over the semiconductor substrate; and
forming a plurality of gate line patterns in parallel with each other by patterning the hard mask layer, the conductive layer and the tunnel insulating layer.

16. The method of claim 12, wherein the forming of the auxiliary layer comprises:
etching the first insulating layer to expose top portions of the first and second air gaps;
forming a mask pattern covering the first insulating layer in the second memory cell region and opening the first insulating layer in the first memory cell region; and
forming an auxiliary layer along a surface of the first air gap having the top portion exposed so that the dimension of the first air gap is substantially smaller than the dimensions of the second air gap.

17. The method of claim 16, further comprising, after the forming of the auxiliary layer:
removing the mask pattern; and
forming a second insulating layer over the first insulating layer to cover openings of the first and second air gaps.
